(19) United States
(12) Patent Application Publication
(10) Pub. No.: US 2009/0251878 A1
(43) Pub. Date: Oct. 8, 2009

(54) Electronic Assembly and Method for Making Electronic Devices

(76) Inventors: Tsung-Hsien Hsu, Changhua County (TW); Te-Fang Chu, Nantou County (TW); Hsing-Lung Chung, Nantou County (TW)

Correspondence Address: FROMMER LAWRENCE & HAUG LLP, 745 FIFTH AVENUE, NEW YORK, NY, 10151, US

(21) Appl. No.: 12/061,208

(22) Filed: Apr. 2, 2008

(51) Int. Cl. H05K 7/02; H01L 21/50

(52) U.S. Cl. 361/820; 438/113; 257/E21.499

(57) ABSTRACT

An electronic assembly includes: a circuit substrate with a first mounting surface that has a plurality of spaced apart first mounting regions and at least one second mounting region spaced apart from the first mounting regions; a plurality of first electronic components mounted on the first mounting regions, respectively; and at least one dummy of a non-electronic component mounted on the second mounting region and having dimensions simulating those of the first electronic components. A method for making electronic devices is also disclosed.

### BACKGROUND OF THE INVENTION

1. Field of the Invention

This invention relates to an electronic assembly and a method for making electronic devices.

2. Description of the Related Art

As shown in FIG. 1, an electronic device 10 includes a substrate 13, a chip 11 mounted on a first surface 131 of the substrate 13, and a plurality of electronic elements 12 mounted on a second surface 132 of the substrate 13.

FIGS. 2 to 4 show a process for making the electronic device 10. As shown in FIG. 2, a plurality of chips 11 and a plurality of electronic elements 12 are mounted on a substrate sheet 2. As shown in FIGS. 3 and 4, the chips 11 mounted on the substrate sheet 2 are adhered to a frame 15 using an adhesive tape 14 so as to form an electronic assembly 1. The electronic assembly 1 is then cut into a plurality of electronic devices 10 along cutting lines (X) and (Y) using a cutting machine.

Prior to mounting of the chips 11 and the electronic elements 12 on the substrate sheet 2, the substrate sheet 2 is examined to identify defective regions 13′ and effective regions thereof so that only effective regions of the substrate sheet 2 are provided with the chips 11 and the electronic elements 12. Unlike the effective regions of the substrate sheet 2 that are connected to the adhesive tape 14 through the chips 11 mounted thereon, the defective regions 13′ are free from connection to the adhesive tape 14. As a consequence, during cutting, the defective regions 13′ are likely to be flung due to rotation of a knife of the cutting machine, thereby resulting in damage to the cutting machine. If the damaged knife is not immediately replaced, the electronic devices 10 thus manufactured will be damaged thereby, thus resulting in manufacturing loss.

### SUMMARY OF THE INVENTION

Therefore, the object of the present invention is to provide an electronic assembly and a method for making electronic devices that can overcome the aforesaid drawback of the prior art.

According to one aspect of this invention, an electronic assembly includes: a circuit substrate with a first mounting surface that has a plurality of spaced apart first mounting regions and at least one second mounting region spaced apart from the first mounting regions; a plurality of first electronic components mounted on the first mounting regions, respectively; and at least one dummy of a non-electronic component mounted on the second mounting region and having dimensions simulating those of the first electronic components.

According to another aspect of this invention, a method for making electronic devices includes: preparing a circuit substrate having a first mounting surface that has a plurality of mounting regions; detecting the circuit substrate to identify effective and ineffective regions from the mounting regions of the first mounting surface of the circuit substrate; mounting a plurality of first electronic components and at least one dummy of a non-electronic component on the effective and ineffective regions, respectively; attaching an adhesive tape to the first electronic components and the dummy; attaching a frame to the adhesive tape; and cutting the circuit substrate along predetermined cutting lines so as to form the electronic devices, each of which includes a respective one of the first electronic components and a cut portion of the circuit substrate that defines a respective one of the effective regions of the first mounting surface.

### BRIEF DESCRIPTION OF THE DRAWINGS

Other features and advantages of the present invention will become apparent in the following detailed description of the preferred embodiment of this invention, with reference to the accompanying drawings, in which:

FIG. 1 is a cross-sectional view of a conventional electronic device;

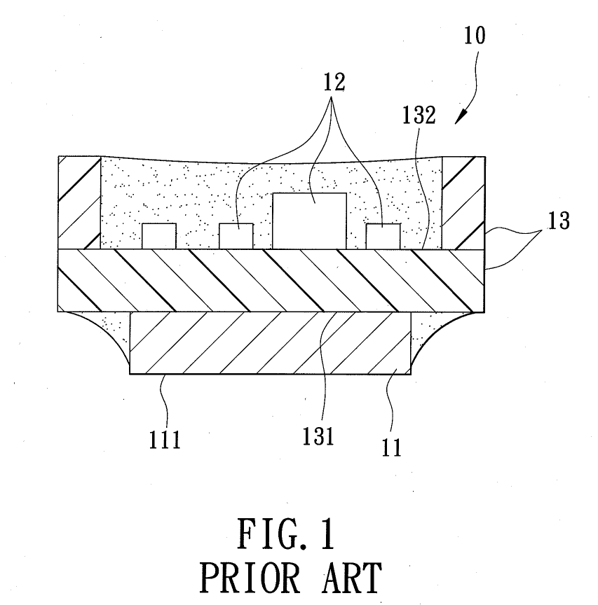

FIG. 2 is a cross-sectional view of a conventional electronic assembly;

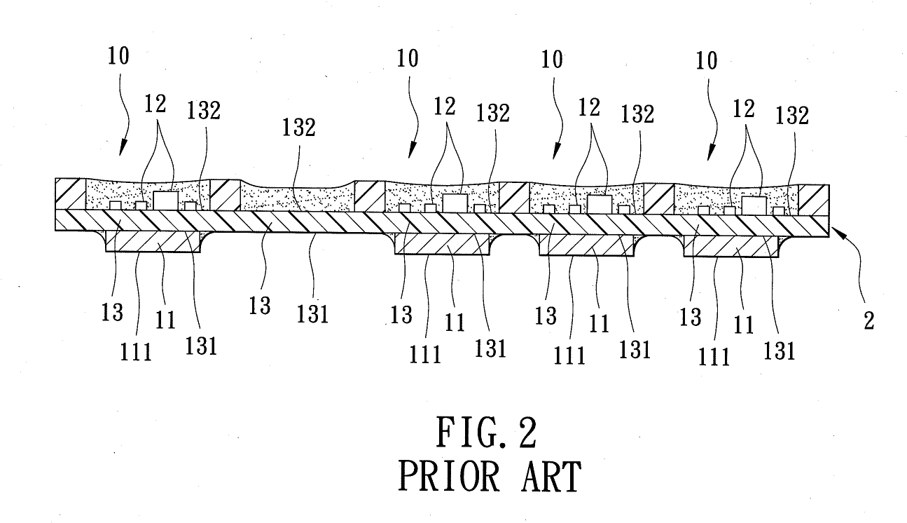

FIG. 3 is a schematic top view of the conventional electronic assembly shown in FIG. 2, showing defective regions of a substrate;

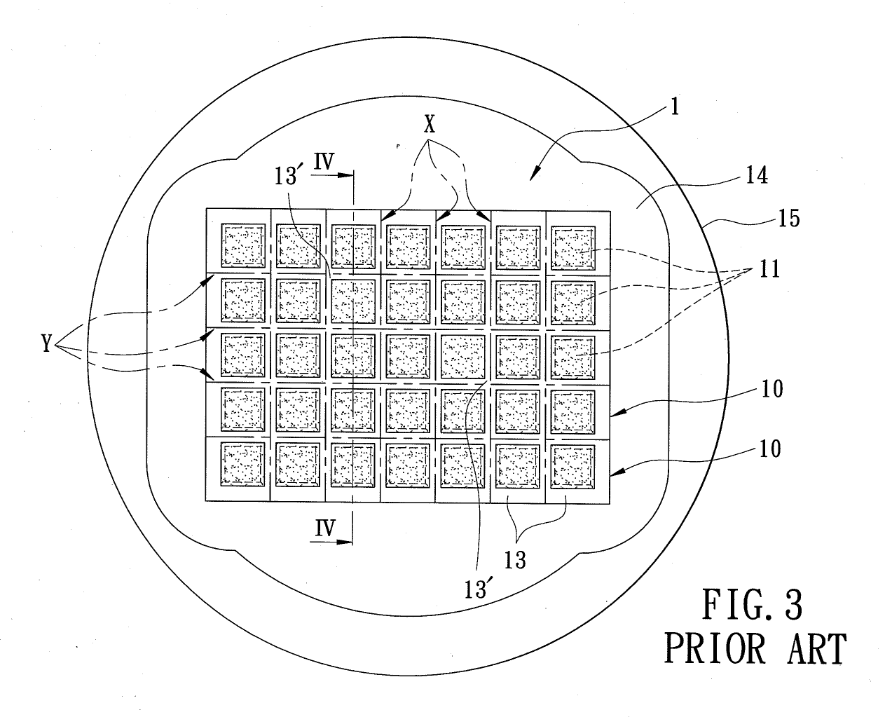

FIG. 4 is a cross-sectional view of the conventional electronic assembly taken along line IV-IV of FIG. 3;

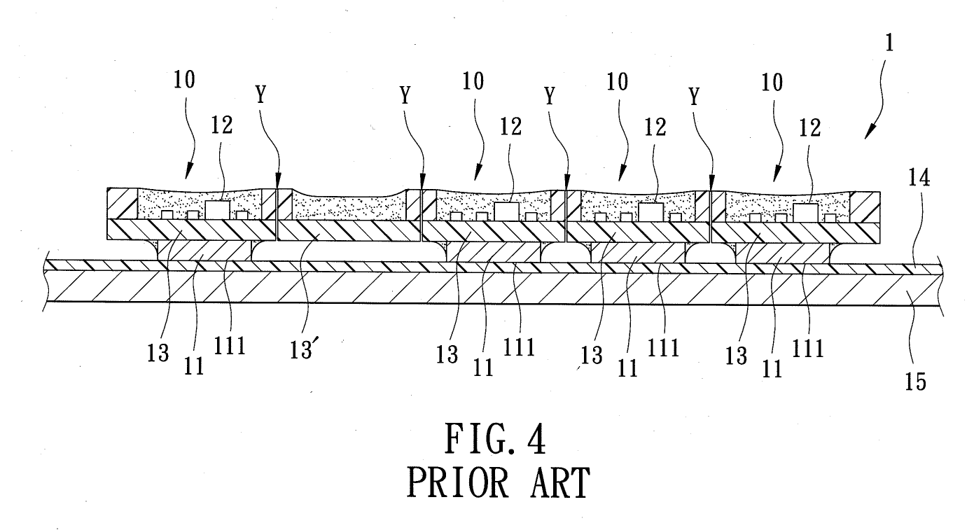

FIG. 5 is a cross-sectional view of the preferred embodiment of an electronic assembly according to this invention;

FIG. 6 is a schematic top view of the preferred embodiment shown in FIG. 5; and

FIG. 7 is a schematic cross-sectional view of the preferred embodiment taken along line VII-VII of FIG. 6.

### DETAILED DESCRIPTION OF THE PREFERRED EMBODIMENT

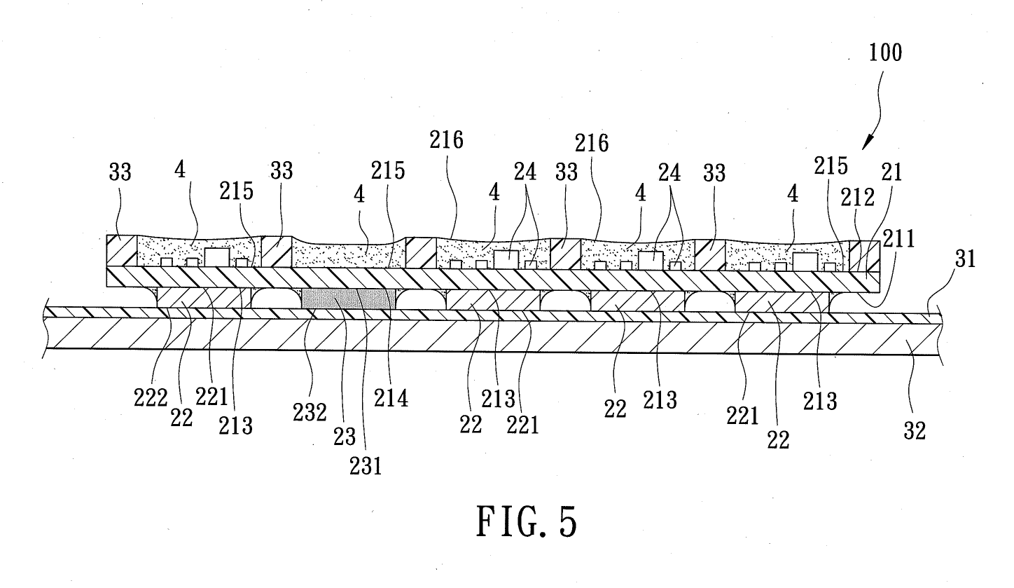

Referring to FIGS. 5 to 7, the preferred embodiment of an electronic assembly 100 according to the present invention is shown to include: a circuit substrate 21 having a first mounting surface 211 and a second mounting surface 212 opposite to the first mounting surface 211; a plurality of first electronic components 22 (i.e., semiconductor chips) mounted on the first mounting surface 211; a plurality of second electronic components 24 (e.g., capacitors, resistors, and/or chips) mounted on the second mounting surface 212, and at least one dummy 23 of a non-electronic component mounted on the first mounting surface 211 and having dimensions simulating those of the first electronic components 22.

Each of the first electronic components 22 and the dummy 23 has a substrate-contact surface 221, 231 attached to the first mounting surface 211 of the circuit substrate 21, and a tape-contact surface 222, 232 opposite to the substrate-contact surface 221, 231. The tape-contact surfaces 222, 232 of the first electronic components 22 and the dummy 23 are coplanar.

Specifically, the first mounting surface 211 of the circuit substrate 21 has a plurality of spaced apart first mounting regions (i.e., effective regions) 213 and at least one second mounting region (an ineffective region or a defective region) 214 spaced apart from the first mounting regions 213. The first electronic components 22 are mounted on the first mounting regions 213, respectively. The dummy 23 is mounted on the second mounting region 214. The second mounting surface 212 of the circuit substrate 21 has a plurality of mounting regions 215 corresponding respectively to the first and second mounting regions 213, 214 of the first mounting surface 211. A confining substrate 33 is provided on the second mounting surface 212 of the circuit substrate 21, and is formed with a plurality of through-holes 216 for exposing the mounting regions 215 of the second mounting surface 212 of the circuit substrate 21, respectively. The second electronic components 24 are respectively mounted on the mounting regions 215 of the second mounting surface 212 in the through-holes 216, followed by filling the through-holes 216 with an encapsulant 4 to enclose the second electronic components 24.

Preferably, the dummy 23 is made from an inexpensive material, e.g., a plastic material.

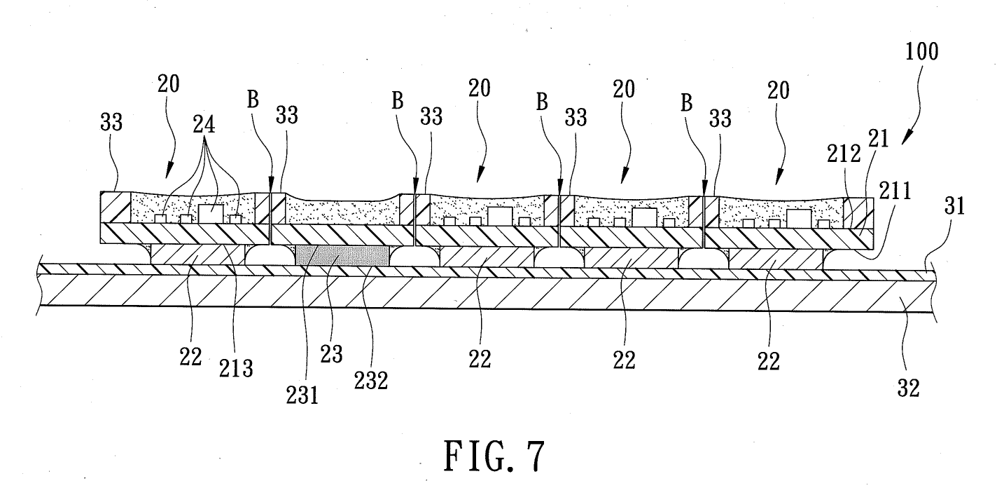

The electronic assembly 100 further includes an adhesive tape 31 attached to the tape-contact surfaces 222, 232 of the first electronic components 22 and the dummy 23, and a frame 32 attached to the adhesive tape 31 (see FIGS. 5 and 7).

The electronic assembly 100 of this invention is made by the following steps.

First of all, a circuit substrate 21 is provided. The circuit substrate 21 has a first mounting surface 211 having a plurality of mounting regions, and a second mounting surface 212.

The circuit substrate 21 is detected to identify effective portions and defective portions thereof. The mounting regions of the first mounting surface 211 in the effective portions and in the defective portions of the circuit substrate 21 are referred as first mounting regions (effective regions) 213 and second mounting regions (ineffective regions) 214, respectively.

Then, a plurality of first electronic components 22 and at least one dummy 23 (i.e., anon-electronic component) are mounted on the first and second mounting regions 213, 214, respectively. A plurality of second electronic components 24 are mounted on mounting regions of the second mounting surface 212 corresponding respectively to the first mounting regions 213 of the first mounting surface 211 (i.e., the second electronic components 24 are not mounted on the mounting regions of the second mounting surface 212 corresponding respectively to the ineffective regions 214).

An encapsulant 4 is used to seal the first and second electronic components 22, 24, and the dummy 23. An adhesive tape 31 is adhered to the first electronic components 22 and the dummy 23, and a frame 32 is then attached to the adhesive tape 31. The electronic assembly 100 is thus obtained.

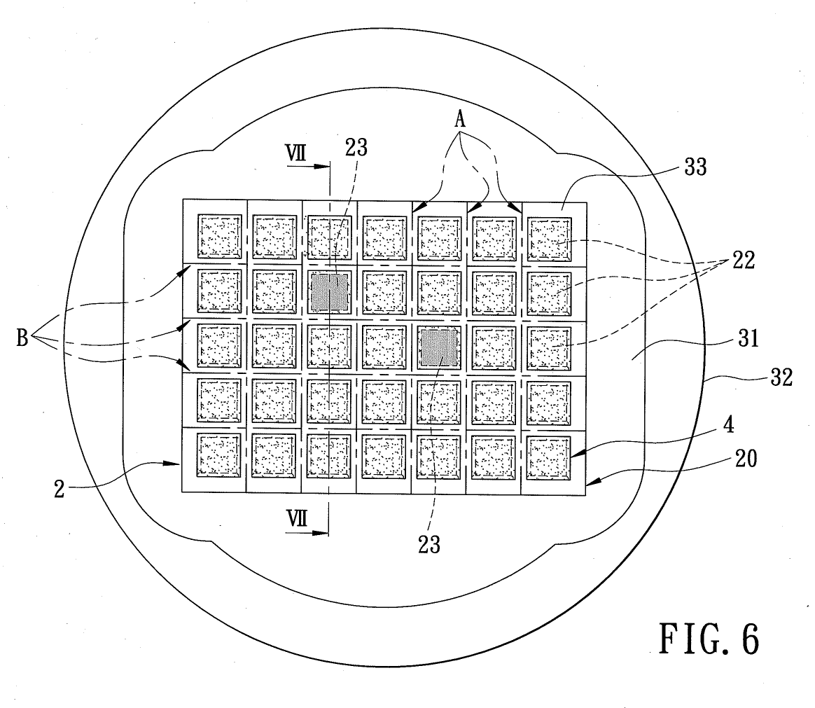

As shown in FIGS. 6 and 7, the electronic assembly 100 is cut along cutting lines (A) and (B), followed by removing the adhesive tape 31 from the first electronic components 22 so as to form a plurality of electronic devices 20. Each of the electronic devices 20 includes the respective first and second electronic components 22, 24 and a cut portion of the circuit substrate 21 that defines a respective one of the effective regions 213 of the first mounting surface 211.

With the inclusion of the dummy 23 in the electronic assembly 100 of this present invention, each of the defective portions of the circuit substrate 21 can be adhered to the frame 32 through the adhesive tape 31, and thus is not free from connection to the adhesive tape 31, thereby eliminating the aforesaid damage to the cutting machine as encountered in the prior art.

While the present invention has been described in connection with what is considered the most practical and preferred embodiment, it is understood that this invention is not limited to the disclosed embodiment but is intended to cover various arrangements included within the spirit and scope of the broadest interpretation and equivalent arrangements.

What is claimed is:

1. An electronic assembly comprising:
a circuit substrate with a first mounting surface that has a plurality of spaced apart first mounting regions and at least one second mounting region spaced apart from said first mounting regions;
a plurality of first electronic components mounted on said first mounting regions, respectively; and
at least one dummy of a non-electronic component mounted on said second mounting region and having dimensions simulating those of said first electronic components.

2. The electronic assembly of claim 1, wherein each of said first electronic components and said dummy has a substrate-contact surface attached to said first mounting surface of said circuit substrate, and a tape-contact surface opposite to said substrate-contact surface, said tape-contact surfaces of said first electronic components and said dummy being coplanar.

3. The electronic assembly of claim 2, further comprising an adhesive tape attached to said tape-contact surfaces of said first electronic components and said dummy.

4. The electronic assembly of claim 3, further comprising a frame attached to said adhesive tape.

5. The electronic assembly of claim 1, wherein said dummy is made from a plastic material.

6. The electronic assembly of claim 1, wherein said circuit substrate further has a second mounting surface opposite to said first mounting surface, having a plurality of mounting regions corresponding respectively to said first and second mounting regions of said first mounting surface, and provided with a confining substrate thereon, said confining substrate being formed with a plurality of through-holes exposing said mounting regions of said second mounting surface of said circuit substrate, respectively.

7. The electronic assembly of claim 6, further comprising a plurality of second electronic components mounted on said mounting regions of said second mounting surface of said circuit substrate within said through-holes in said confining substrate, respectively.

8. The electronic assembly of claim 1, wherein each of said first electronic components is a semiconductor chip.

9. A method for making electronic devices comprising:
preparing a circuit substrate having a first mounting surface that has a plurality of mounting regions;
detecting the circuit substrate to identify effective and ineffective regions from the mounting regions of the first mounting surface of the circuit substrate;
mounting a plurality of first electronic components and at least one dummy of a non-electronic component on the effective and ineffective regions, respectively;
attaching an adhesive tape to the first electronic components and the dummy;
attaching a frame to the adhesive tape; and
cutting the circuit substrate along predetermined cutting lines so as to form the electronic devices, each of which includes a respective one of the first electronic components and a cut portion of the circuit substrate that defines a respective one of the effective regions of the first mounting surface.

10. The method of claim 9, wherein each of the first electronic components and the dummy has a substrate-contact surface attached to the first mounting surface of the circuit substrate, and a tape-contact surface opposite to the substrate-contact surface, the tape-contact surfaces of the electronic components and the dummy being coplanar.

11. The method of claim 9, wherein the dummy is made from a plastic material.

12. The method of claim 9, wherein the circuit substrate further has a second mounting surface opposite to the first mounting surface, having a plurality of mounting regions corresponding respectively to the effective and ineffective regions of the first mounting surface, and provided with a confining substrate thereon, the confining substrate being formed with a plurality of through-holes exposing the mounting regions of the second mounting surface of the circuit substrate, respectively.

13. The method of claim 12, further comprising, before attaching the adhesive tape, mounting a plurality of second electronic components on the mounting regions of the second mounting surface of the circuit substrate within the through-holes in the confining substrate, respectively.

14. The method of claim 9, wherein each of the first electronic components is a semiconductor chip.
